(19) United States
(12) Patent Application Publication
(10) Pub. No.: US 2008/0084665 A1
(43) Pub. Date: Apr. 10, 2008

(54) HEAT SINK AND MANUFACTURING METHOD THEREFOR

(76) Inventor: Neil Charles Tigwell, Witney (GB)

Correspondence Address: SCHIFF HARDIN, LLP;PATENT DEPARTMENT, 6600 SEARS TOWER, CHICAGO, IL, 60606-6473, US

(21) Appl. No.: 11/867,899

(22) Filed: Oct. 5, 2007

(30) Foreign Application Priority Data
Oct. 5, 2006 (GB) 0619683.6

(51) Int. Cl. H05K 7/20; B21D 53/02

(52) U.S. Cl. 361/699; 29/890.03

(57) ABSTRACT

A heat sink has a structure fabricated of aluminum, with at least a portion of this structure having a surface with at least a portion thereof exposed to a device to be cooled and/or to a coolant liquid at least this portion being hard-anodized. This portion of the structure is rendered electrically insulating and/or corrosion resistant by a hard-anodized surface layer thereon.

### BACKGROUND OF THE INVENTION

1. Field of the Invention

The present invention relates to heat sinks of the type usable, for example, for cooling electrical components and relates especially, though not exclusively, to heavy duty heat sinks that are constructed to accept a flow of liquid coolant therethrough.

2. Description of the Prior Art

As greater demands in terms of power handling and functional capabilities are imposed upon electrical components, there is a correspondingly greater requirement for cooling such components, to ensure that they run at temperatures consistent with their operational limitations.

Accordingly, considerable effort has been expended on the development of adequate cooling devices for such components and, whilst liquid-cooled heat sinks currently used are, generally speaking, quite effective, they have been developed piecemeal, with individual problems discovered in service being addressed with individual solutions. This leads to difficulties associated with (a) the construction of complex structures and the accompanying cost, and (b) the creation of heat sinks which offer limited overall efficiency, in terms of cooling power in relation to space occupied.

### SUMMARY OF THE INVENTION

An object of the present invention is to overcome or reduce at least one of the above-mentioned difficulties. It is a further object of the invention to provide a liquid-cooled heat sink of unitary construction. A still further object of the invention is to provide a liquid-cooled heat sink requiring no external pipe-work links between internal liquid conduits, thereby permitting the effective dimensions of the heat sink to be increased as compared with those for a heat sink with external pipe-work connections.

The invention also encompasses methods of making heat sinks of the kinds mentioned in the immediately preceding paragraph.

The above object is achieved in accordance with the present invention by a heat sink having an aluminum structure having a first surface having at least a portion thereof in thermal communication with a device to be cooled, and a second surface that is exposed to a coolant liquid, the second surface having a hard-anodized surface layer thereon that is resistant to attack, such as corrosion, by the coolant liquid.

The above object also is achieved in accordance with the present invention by a method for manufacturing a heat sink including the steps of fabricating a heat sink structure from aluminum, forming a channel in the structure that is configured to accept a liquid coolant flowing therein, and applying a surface coating to a surface of the channel, which is resistant to attack, such as corrosion, by the coolant liquid, the surface coating being applied by hard-anodizing the surface of the channel.

### BRIEF DESCRIPTION OF THE DRAWINGS

FIGS. 1A and 1B show, in elevation and plan views, respectively, a typical prior art heat sink.

FIGS. 2A and 2B show, in views comparable to those of FIGS. 1A and 1B respectively, a heat sink in accordance with an embodiment of the present invention.

### DESCRIPTION OF THE PREFERRED EMBODIMENTS

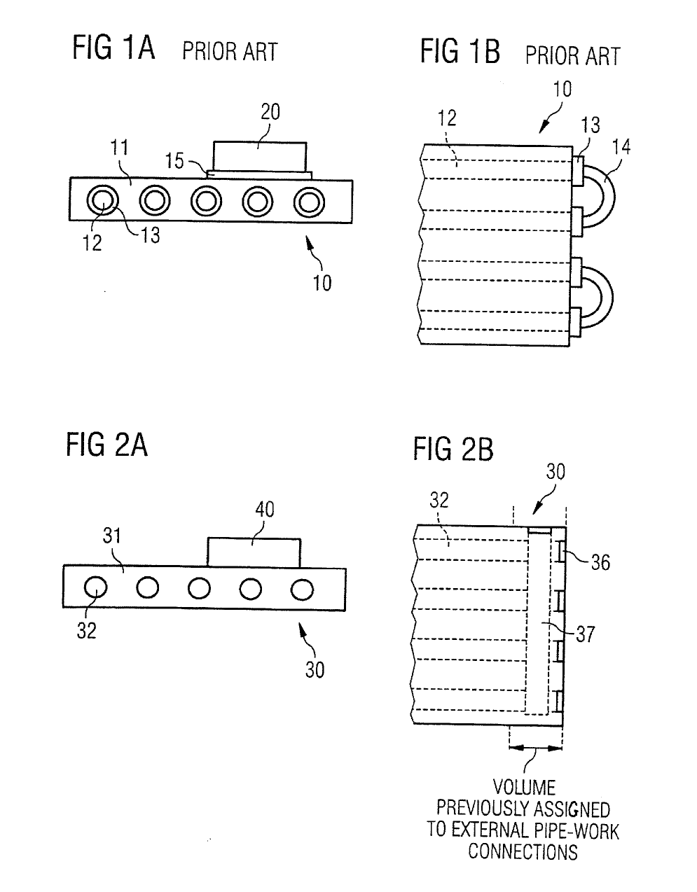

Referring now to FIGS. 1A and 1B, a typical prior art heat sink 10, provided for cooling an electrical device 20, comprises an extruded plate 11 of aluminum. The plate 11 may be finned or otherwise treated to promote dissipation of heat from the external surfaces thereof.

Similar heat sinks are available from R-Theta Thermal Solutions Inc (www.r-theta.com) under the “Aquasink” brand.

The plate 11 is formed with internal channels such as 12 though which, in use, liquid coolant such as water is caused to flow. The channels such as 12 are fitted with tubular copper liners such as 13 used to provide resistance to corrosion of the plate 11 by the liquid coolant. The tubular liners such as 13 may be threaded at their ends, and are interconnected, externally of the aluminum plate 11, for example by stainless steel pipe-work interconnects, such as 14, creating a desired liquid flow pattern through the plate 11 to promote enhanced dissipation of heat generated by the device 20.

Typically, the device 20 needs to be attached to the heat sink 10, so as to establish good thermal contact therewith, whilst remaining electrically insulated therefrom. This is usually achieved by means of an adhesive pad or film 15 of thermally conductive but electrically insulating material.

Referring now to FIGS. 2A and 2B, which show, as an example only, an embodiment of the invention. The heat sink 30 of this embodiment is provided for cooling an electrical device 40 and has an extruded aluminum plate 31, containing, as is conventional, parallel flow channels such as 32 for liquid coolant such as water. In this case, however, unlike the prior art configuration described with reference to FIGS. 1A and 1B, no liners such as 13 are used in the coolant flow channels. In accordance with this embodiment of the invention, resistance to corrosion of the aluminum by the coolant fluid, with no substantial reduction in thermal transfer efficiency, is provided by hard anodizing the exposed surfaces of the channels, such as 32.

This procedure advantageously allows the cooling channels to have a larger bore compared to the prior art, since the copper liners such as 13 are not used.

In a further refinement employed by this embodiment, the external pipe-work connections between channels, such as shown at 14 in the prior art heat sink of FIG. 1B, are not required. According to this refinement, individual channels such as 32 are plugged, as shown at 36, and an orthogonal linking channel 37, also hard-anodized and plugged, is provided to interlink the channels such as 32 to provide a desired flow pattern for the liquid coolant. Further linking channels such as 37 may be provided as required to establish a required coolant flow path. Each linking channel serves to join at least two of the channels 32.

Such interconnection of channels within the material of the plate is not possible with the prior art heat sinks such as shown in FIGS. 1A and 1B, since interconnection of copper liners 13 would then be required. Since the described embodiment of the present invention employs no liners, but rather employs channels formed in the bulk material of the aluminum plate 31, such interconnection is made possible by the present invention.

The plugging 36 may be of aluminum or any other material suitable for the intended temperature range of operation, and compatible with the aluminum material of the plate 31. The linking channel 37 is drilled into the aluminum plate 31 generally perpendicularly to the channels 32, parallel to the plane of the channels 32 to connect at least two of the channels 32. If desired, further linking channels may be provided at other positions within the aluminum plate. Hard-anodizing of the channels should be done after formation of the linking channel(s) 37. Depending on the material used for plugging 36 channels 32, 37, the hard-anodizing may need to be done after plugging is complete.

As can be seen from a comparison of FIGS. 1B and 2B, this refinement not only provides a significant component and cost reduction, but also permits an increase in the size of the active heat sinking volume of the heat sink 30 compared with that of the heat sink 10, since the volume previously occupied by the external pipe-work connections such as 14 can now be assigned to the bulk of the heat sink 30 itself, giving greater heat sink volume within the same external volumetric envelope. It will be appreciated that the dimensions of the external volumetric envelope are frequently pre-assigned in any given configuration, so that an increase in the active heat sinking volume within this pre-assigned envelope provides added cooling efficiency.

The invention also provides, in this embodiment, efficient electrical insulation between the heat sink 30 and the electrical device 40, by hard-anodizing that part of the surface area of the plate 32 to which the device 40 is attached. The hard-anodized surface area provides excellent thermal transfer efficiency coupled with electrical insulation.

It will be understood that the hard-anodizing required by the invention can be employed in relation to the surfaces of the coolant channels and/or the surface area or areas at which devices to be cooled are attached to the heat sink.

It will be further understood that the hard-anodizing can be implemented in any suitable manner and that, if desired or if convenient, the entire external and internal surface area of the aluminum structure, such as plate 31, may be hard-anodized.

The present invention has been described with particular reference to extruded aluminum plates 31, containing parallel cooling channels 32 formed during the extrusion process. In alternative embodiments, the required channels may be formed by drilling or otherwise machining into a solid block of material. In a further alternative, linking channel(s) 37 are formed during extrusion of an extruded aluminum plate, with coolant channels 32 formed by drilling or otherwise machining into the extruded plate.

The present invention accordingly provides hard-anodizing both to the interior surfaces of the channels, to provide a thin corrosion resistant coating, and to the surface area of the plate to which the device 40 is attached, to provide electrical isolation between the plate and the cooled device. It has been found simplest to perform anodizing over the entire internal and external surfaces of the aluminum plate.

Although modifications and changes may be suggested by those skilled in the art, it is the intention of the inventor to embody within the patent warranted hereon all changes and modifications as reasonably and properly come within the scope of his contribution to the art.

I claim as my invention:

1. A heat sink comprising:
an aluminum structure having a first surface with at least a portion thereof configured to be in thermal communication with a device to be cooled, and having a second surface configured to be exposed to a coolant liquid; and
said second surface having a hard-anodized layer thereon that is resistant to attack by said coolant liquid.

2. A heat sink as claimed in claim 1 comprising a hard-anodized layer on said first surface that is electrically insulating.

3. A heat sink as claimed in claim 1 wherein said aluminum structure comprises channels configured to receive a flow of the liquid coolant therein, and wherein said second surface comprises respective internal surfaces of said channels.

4. A heat sink as claimed in claim 3 wherein said channels proceed substantially parallel with each other in said aluminum structure.

5. A heat sink as claimed in claim 3 wherein said channels are first channels, and wherein said aluminum structure comprises at least one second channel placing at least two of said first channels in fluid communication with each other.

6. A heat sink as claimed in claim 1 wherein said aluminum structure comprises a plate of extruded aluminum.

7. A heat sink as claimed in claim 6 comprising fins on said plate.

8. A heat sink as claimed in claim 1 wherein an entirety of said first surface and said second surface of said aluminum structure is hard-anodized.

9. A method of making a heat sink comprising the steps of:
fabricating a heat sink structure from aluminum;
in said heat sink structure, forming at least one channel configured to receive a liquid coolant flow therein; and
applying a surface coating to a surface of said channel by hard-anodizing said surface of said channel to make said surface of said channel resistant to attack by the liquid coolant.

10. A method as claimed in claim 9 wherein said heat sink structure has an exterior surface configured to be in thermal communication with a device to be cooled, and comprising electrically insulating at least a portion of said exterior surface by hard-anodizing at least said portion of said exterior surface.

11. A method as claimed in claim 9 comprising fabricating said heat sink structure by extruding aluminum.

12. A method as claimed in claim 9 comprising hard-anodizing all surfaces of said heat sink structure to give said heat sink structure an entire surface area that is both resistant to attack by said coolant liquid and electrically insulating.
